(19) United States
(12) Patent Application Publication
(10) Pub. No.: US 2011/0218749 A1
(43) Pub. Date: Sep. 8, 2011

(54) BRANCH CIRCUIT POWER MONITORING APPARATUS & RELATED METHODS

(75) Inventor: Scott L. Bassford, Decorah, IA (US)

(73) Assignee: NORTH APPLICATIONS LLC, Decorah, IA (US)

(21) Appl. No.: 13/034,879

(22) Filed: Feb. 25, 2011

Related U.S. Application Data
(60) Provisional application No. 61/310,415, filed on Mar. 4, 2010.

(51) Int. Cl. G01R 15/18; G06F 19/00; G01R 19/25

(52) U.S. Cl. 702/64; 324/127

(57) ABSTRACT

A system for monitoring and reporting power consumption in a branch circuit electrical panel is disclosed. The system uses split core transformers to sense current and voltage within the electrical panel. Each circuit within the electrical panel is sampled periodically. The periodically sampled voltages and currents are transformed into power consumption data. The power consumption data is communicated to a remote server computer. The remote server computer generates reports regarding the power consumption of the various circuits within the electrical panel. A remote computer may be used to access the reports from the server. Note that this abstract is presented to meet requirements of the USPTO. This abstract is not intended to identify key elements of the apparatus and methods disclosed herein or to delineate the scope thereof.

### CROSS-REFERENCE TO RELATED APPLICATIONS

The present application claims priority and benefits of U.S. Provisional Patent Application 61/310,415 by applicant Scott L. Bassford entitled “BRANCH CIRCUIT POWER MONITORING DEVICE” filed on 4 Mar. 2010, which is hereby incorporated by reference in its entirety herein.

### BACKGROUND

1. Field

This apparatus and associated methods disclosed herein relate generally to monitoring and reporting devices for use in monitoring and reporting power usage in a branch electrical circuit.

2. Related Art

Residential and commercial buildings typically include electrical circuit panels. These circuit panels may include breakers, and other devices for controlling electrical circuits within the building. There is a need for improved branch circuit power monitoring apparatus that can monitor individual circuits within the breaker box.

### BRIEF SUMMARY

These and other needs and disadvantages may be overcome by the apparatus and methods disclosed herein. Additional improvements and advantages may be recognized by those of ordinary skill in the art upon study of the present disclosure.

A branch circuit power monitoring system is disclosed herein. In various aspects, the branch circuit power monitoring apparatus includes a current transformer adapted to communicate with a circuit that receives power from an electrical panel to detect the current within the circuit, and a converter in operable connection with the current transformer to sample intermittently a current transformer signal from the current transformer indicative of the current. The converter is adapted to generate a digital data signal indicative of the current, in various aspects.

This summary is presented to provide a basic understanding of some aspects of the apparatus and methods disclosed herein as a prelude to the detailed description that follows below. Accordingly, this summary is not intended to identify key elements of the apparatus and methods disclosed herein or to delineate the scope thereof.

### BRIEF DESCRIPTION OF THE DRAWINGS

FIG. 1 is a schematic of an exemplary implementation of a branch circuit power monitoring apparatus;

FIG. 2 is a schematic of portions of the exemplary implementation of a branch circuit power monitoring apparatus generally illustrated in FIG. 1;

FIG. 3 is an exemplary circuit diagram of a circuit used in the exemplary implementation of a branch circuit power monitoring apparatus of FIG. 1;

FIG. 4 illustrates by schematic portions of an exemplary implementation of a branch circuit power monitoring apparatus in communication with circuits within an electrical panel

FIG. 5 is an exemplary display screen with a report regarding power consumption generated by a remote server according to an exemplary implementation of a branch circuit power monitoring apparatus;

FIG. 6 illustrates by process flow chart an exemplary method of collecting and uploading data to a remote server; and,

FIG. 7A illustrates graphically an implementation of intermittent sampling of a current transformer signal from the current transformer indicative: and

FIG. 7B illustrates graphically an implementation of intermittent sampling of a reference voltage signal from the reference voltage transformer.

The Figures are exemplary only, and the implementations illustrated therein are selected to facilitate explanation. The number, position, relationship and dimensions of the elements shown in the Figures to form the various implementations described herein, as well as dimensions and dimensional proportions to conform to specific force, weight, strength, flow and similar requirements are explained herein or are understandable to a person of ordinary skill in the art upon study of this disclosure. Where used in the various Figures, the same numerals designate the same or similar elements. Furthermore, when the terms “top,” “bottom,” “right,” “left,” “forward,” “rear,” “first,” “second,” “inside,” “outside,” and similar terms are used, the terms should be understood in reference to the orientation of the implementations shown in the drawings and are utilized to facilitate description thereof.

### DETAILED DESCRIPTION

In various aspects, a branch circuit monitoring apparatus may include one or more circuit monitors, which may be current transformers. Each of the one or more circuit monitors may be in communication with a corresponding circuit of an electrical panel to detect the voltage and current within the circuit. The circuit monitor may communicate one or more digital values representative of the voltage, the current, or the power within the circuit to a computer. The computer may be located generally on site (i.e. the same facility) or may be remotely located geographically with respect to the circuit. The computer may conduct various analyses of the voltage, current, or power, and the results of these analyses may be displayed graphically, in a tabular form, or otherwise communicated to a user. The computer may communicate with various devices that are in communication with the circuit to modulate the operation of these devices in order to adjust the power drawn from the circuit by these devices.

In various aspects, the branch circuit power monitoring apparatus uploads usage data to a server. The branch circuit power monitoring apparatus may be installed within a branch circuit electrical panel, or may be installed near the electrical panel. The branch circuit monitoring apparatus samples multiple channels of current draw and one or more channels of AC voltage references.

A voltage divider may be used to connect current transformers and the AC voltage reference transformer to a voltage midway between the ground and positive voltages. The voltage midway between the ground and the positive voltages may be about 2.5 volts or may be 1.65 volts, in various aspects.

An analog to digital converter (“A-D converter”) receives inputs from the voltage divider, the AC voltage reference transformer, and the current transformers, in various aspects. In various aspects, multiple A-D converters may be used. The A-D converters may be connected to a microcontroller, and the microcontroller may upload data periodically, for example, once per minute to a remote server. The remote server may be generally on site or may be in a geographically remote location in various aspects. The microcontroller may store data for an extended period, if the remote server is unreachable due to a connection problem.

The current transformers are sampled intermittently, rather than on a continuous basis, by the A/D converter in various aspects. For example, a current transformer may be sampled over a 250 milliseconds interval once per minute, and the current transformer would not be sampled for the remainder of the minute. In various aspects, the power consumption of each circuit is reported in watts. Sampling of current transformers and, thus, the sampling of the circuits being monitored by the current transformers, in various aspects, occurs once per minute for a period of about 250 milliseconds per circuit, and several hundred samples of current waveform and voltage waveform may be taken. The samples may be analyzed to provide RMS readings of voltage, volts amperes—voltage multiplied by RMS amperes and also wattage, the average of multiplying the individual samples of current waveform and voltage waveform. Sampling of current transformers may occur once per minute for a period ranging from about 100 milliseconds to about 1.5 seconds, in various aspects. The current transformers may be sampled intermittently with various other intermittencies in other aspects. In various aspects, the current transformers are split core transformers, such that it is not necessary to take the lines off load during installation.

The voltage divider may be sampled intermittently by the A/D converter, in various aspects. For example, the voltage divider may be sampled for a period ranging from about 100 milliseconds to about 1.5 seconds, in various aspects. The voltage divider may be sampled intermittently with various other intermittencies in various aspects.

In one aspect the present invention is directed to a branch circuit power monitoring apparatus. The circuit power monitoring apparatus includes a channel logger that has a plurality of split core current transformers adapted to sense current within a plurality of circuits in an electrical circuit panel, in this aspect, and each of the current transformers is adapted to periodically sense current within a corresponding circuit. A converter may convert the sensed currents into digital data. A microcontroller may record the digital data. The microcontroller may be adapted to communicate the digital data to a remote server. The remote server may be adapted to generate readable reports based on the data. A voltage reference transformer may be provided. The plurality of split core current transformers may include 14 or 42 current transformers, in various aspects, and the readable reports may include reports that show power consumption by watts.

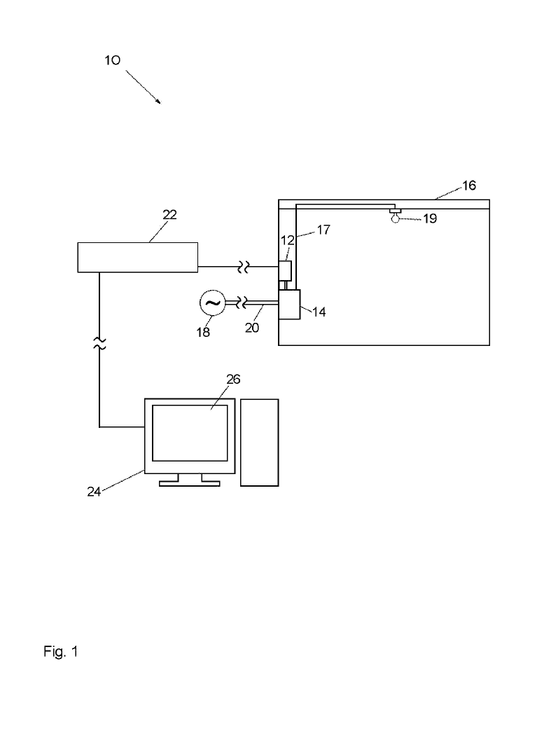

FIG. 1 illustrates an exemplary implementation of a branch circuit power monitoring apparatus 10. The branch circuit power monitoring apparatus 10, in this implementation, includes a circuit monitor 12 operably connected with a branch circuit electrical panel 14. The electrical panel 14 controls the distribution of electricity to electrical circuits 17 to provide alternating current electrical power to outlets and appliances 19 within the building 16. The electrical panel 14 may be supplied by mains electric. The panel 14 distributes the supplied power to electrical circuits 17 and electrical circuits 17 communicate the electrical power from the electrical panel 14. In various implementations, the electrical circuits 17 may communicate alternating current from the electrical panel 14 through portions of a building 16. The building 16 may be, for example, a residential building, such as a home or apartment, or may be a commercial building such as an office building, store or warehouse, a manufacturing facility, an industrial facility such as a refinery, or a farm related facility, or other facility or equipment to which the circuits of the electrical panel communicate. The electrical panel 14 may be used to control electrical distribution to the entire building 16, or to only a portion of the building 16. The electrical panel 14 may include a plurality of circuits, and may include circuit breakers and other controls for the various circuits. Power is distributed to the one or more circuits by the electrical panel so that the circuit(s) are powered by the electrical panel. The electrical circuits within the electrical panel 14 may be single-phase circuits, or may be three-phase circuits. An exemplary electrical panel 14 might include 42 separate electrical circuits.

An electrical power source 18 provides electrical power to the electrical panel 14 through incoming wiring 20. Typically the power source 18 will be an electric utility that transmits electricity through power lines.

The circuit monitor 12 periodically samples and senses voltages and currents within the various circuits in the electrical panel 14, as will be described in more detail below. The circuit monitor 12 determines estimated power consumption in the various circuits based on these voltages and currents. The circuit monitor 12 communicates these sensed voltages and currents as well as the estimated power consumption data to a remote server computer 22. The server 22 is programmed to convert the data into various electronic reports, including power consumption reports in terms of watts consumed for each of the circuits within the electrical panel 14. The electronic reports generated by the server computer 22 may be communicated to a remote computer 24 and displayed on a display screen 26 of the remote computer 24.

It should be appreciated that while the circuit monitor 12 is shown as being mounted outside the electrical panel 14, in practice the circuit monitor 12 may be mounted within the electrical panel 14. Additionally, it should further be appreciated that the circuit monitor 12 may be constructed as a generally single self-contained unit, or may be constructed as a collection of components that are operably connected with each other.

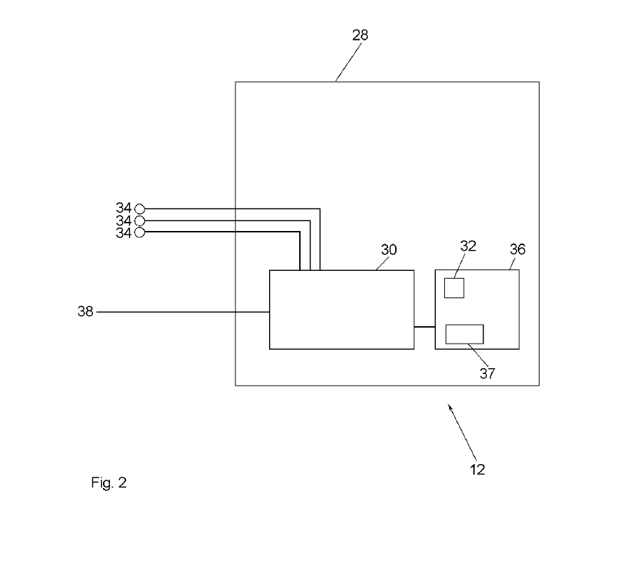

FIG. 2 is a schematic representing an implementation of a self-contained unit for circuit monitor 12. The circuit monitor 12 of FIG. 2 includes an outer shell 28 that is suitable for mounting on or near an electrical panel 14. The outer shell 28 may be provided with a cover (not shown) that can be selectively opened to provide access to the components within the circuit monitor 12. The cover may be attached by hinges, or may be removable from the outer shell 28. The cover may be provided with a lock in order to limit access only to authorized personnel.

Provided within the shell 28 is a logger unit 30 and a power supply unit 36. The logger unit 30 and power supply unit 36 include various components which will be described in more detail for sensing, recording, and communicating the voltage, current, and power consumption within several circuits in an adjoining electrical panel.

The power supply unit 36 includes at least one voltage reference transformer 32 for sensing a reference voltage within the electrical panel. While a single voltage reference transformer 32 is shown, if the circuit monitor 12 is intended for use with a three-phase system, three voltage reference transformers would be needed. The voltage reference transformer 32 receives a reference voltage input from the circuit panel. The power supply unit 36 also includes a power supply apparatus 37 that converts AC to DC to supply power to the various components in the logger unit 30.

A plurality of current transformers 34 are also connected with the logger 30 for connection to individual circuits within the electrical panel. While only three such current transformers 34 are shown in the implementation of FIG. 2, in practice it would be preferred to have at least 14 of such current transformers 34, and in one preferred implementation the logger 30 includes 42 such current transformers 34, in order for the logger 30 to monitor up to 42 separate circuits within the electrical panel 14. Preferably, the current transformers 34 will be split core type transformers such that they can be connected with the individual circuits without the need to rewire the circuits or remove them from load.

The circuit monitor 12 includes a communications outlet 38 for communicating data to a remote server regarding the voltages and currents sensed by the transformers 32 and 34 and the power consumption of the circuits. The communications outlet 38 may be connected with a microcontroller that connects to the server via Ethernet and TCP/IP. According to a preferred implementation, the logger unit 30 will sample the various circuits to which it is connected once per minute, and communicate with the remote server 22 (see FIG. 1) with information regarding each of the circuits one time per minute. Those of skill in the art will understand that other sampling frequencies may be used. Additionally, the information from a series of samplings may be saved and communicated to the remote server 22 on a less frequent basis than the samplings are taken.

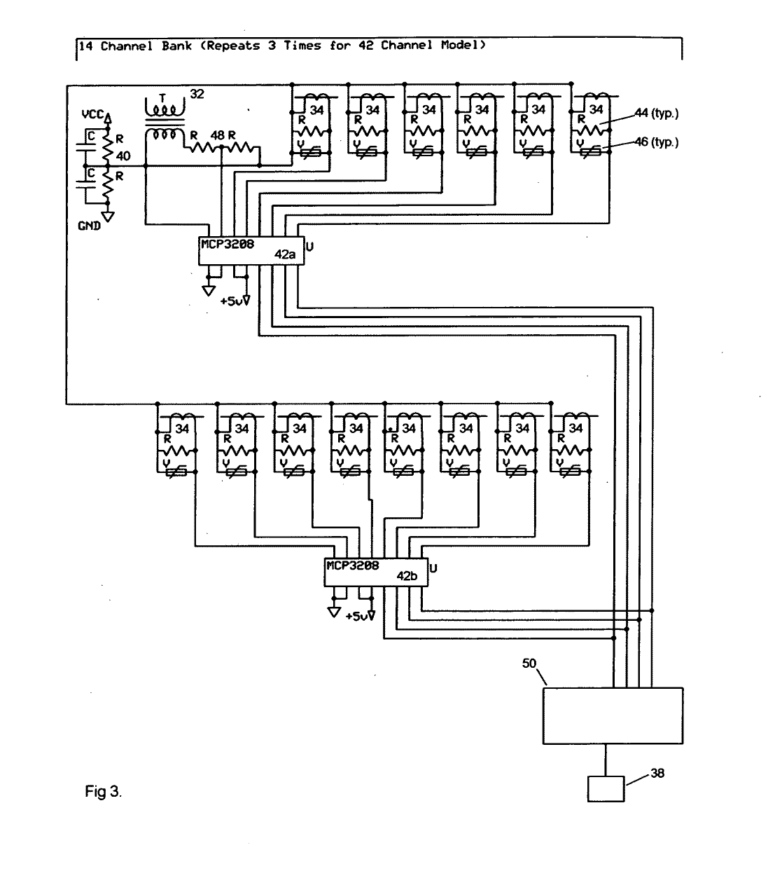

FIG. 3 illustrates by diagram an implementation of the electrical components within circuit monitor 12. The implementation shown in FIG. 3 is for use in a 14-channel logger. Therefore, the circuit includes fourteen current transformers 34. Each of the current transformers 34 are provided with resistors 44 to bring the voltage within an appropriate range. A surge protection varistor 46 is also provided in parallel with the each current transformer 34. According to a preferred implementation, each of the resistors 44 is a 100 ohm resistor.

A voltage divider 40 connects to the current transformers 34 and the voltage reference transformer 32 at a voltage midway between ground and positive. The voltage divider is stabilized with 0.1 μF capacitors. As an alternative to the voltage divider 40, it may be possible to utilize a voltage reference chip.

The voltage reference transformer 32 is a step down transformer that feeds into a voltage divider 40 in order to reduce the output of voltage to an appropriate voltage.

Each of the current transformers 34 and the voltage reference transformer 32 are connected to one of the analog to digital converters 42a and b. According to a preferred implementation, each of the A-D converters 42a and b is a model sold under the brand name Microchip with Model No. MCP3208. A first channel of a first A-D converter 42a is used to measure the voltage divider 40. This compensates for any variations in the manufacturing of the resistors. The second input in the first A-D converter 42a is used to measure the voltage reference received from the voltage reference transformer 32. The remaining inputs on the first A-D converter 42a are used for current measurements received from the current transformers 34. Preferably the A-D converter 42a will have a high impedance. The second A-D converter 42b has all of its inputs connected to current transformers 34.

The A-D converters 42a and b convert the analog signals received at the inputs and provide digital output to a microcontroller 50. The A-D converters 42a and b may be connected to the microcontroller 50 via SPI interface. Firmware embedded on the microcontroller 50 computes the watts, volt amperes and volts for each channel, given the voltage divider input, the AC voltage references, and the multiple current inputs. According to a preferred implementation, the microcontroller may be sold under the brand name Rabbit with Model No. RCM3710. Those of skill in the art will be aware of other microcontrollers that will be suitable for the purpose.

The microcontroller 50 has a communication outlet 38 that connects via Ethernet and TCP/IP to a remote server 22 (not shown, see FIG. 1). According to a preferred implementation, the microcontroller 50 uploads the data to the remote server once per minute. The microcontroller 50 includes a storage medium for storing data, such that it will store several minutes of data if the server is unreachable due to a communication problem, and then upload the data quickly until it catches up to real time.

In one exemplary implementation, each of the individual current transformers 34 is sampled once per minute with a sampling time for each circuit of about 250 milliseconds. Accordingly, the microcontroller 50 records current information and calculates watts, volt amperes, and volts for each channel once per minute. Different frequencies and durations may be used for sampling the individual circuits.

The microcontroller 50 requests the A-D converters 42 to sample the voltage reference transformers 32 and the current transformers 34 several hundred times until 250 milliseconds has elapsed. The microcontroller 50 uses standard algorithms to compute the watts, volt amperes, and volts.

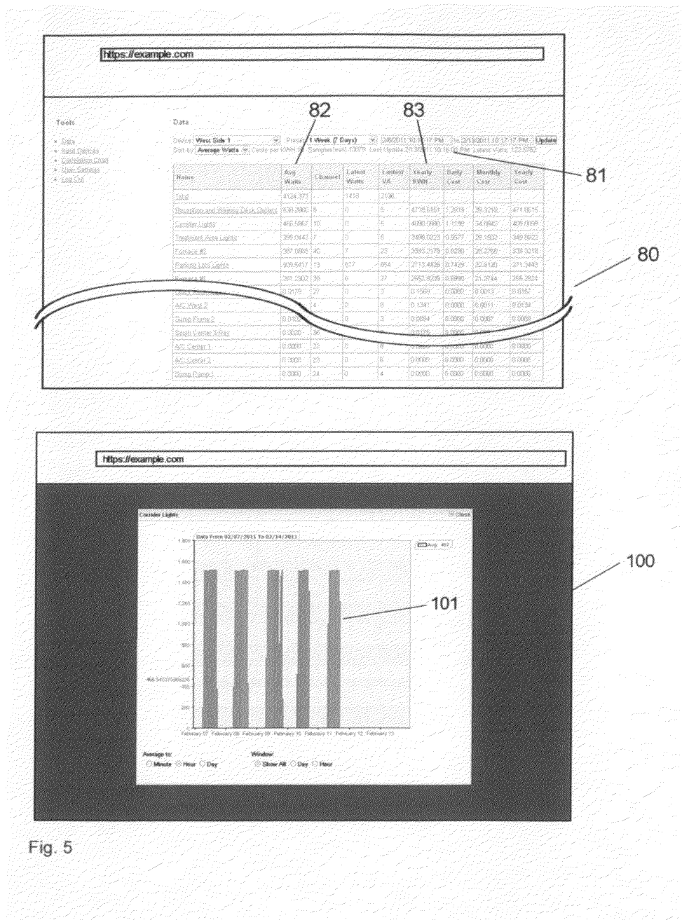

The server 22 is programmed to generate a variety of reports based on the data received from the microcontroller 50. The report generated by the server 22 may be accessed by remote computers via the Internet. FIG. 5 shows an output screen that might be generated on the display screen 26 of a remote computer 24 (see FIG. 1). The reports may be used to graphically display the power consumption within the individual circuit of the electrical panel 14.

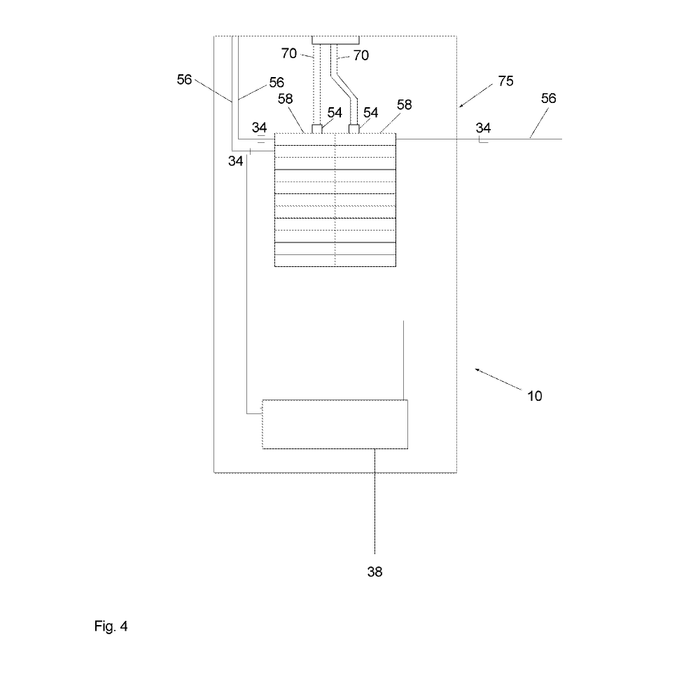

FIG. 4 illustrates an implementation of branch circuit power monitoring apparatus 10 in communication with circuits 56 of electrical panel 75. As illustrated, power is supplied to bus bar 54 in panel 75 through circuit 70 that communicates with mains electric. Circuits 56 extend from buss bar 54 and circuits 56 include breakers 58, as illustrated. In this implementation, breakers 58 are positioned between current transformers 34 and the buss bar 54. In other implementations, not shown, the current transformers 34 may be positioned between the buss bar 54 and the breakers 58. In various implementations, the current transformers 34 may communicate with circuits 56 within panel 14 or with circuits 56 as the circuits extend forth from panel 14.

FIG. 5 illustrates an implementation of a display of consumption data. Last data updated date 81 informs the user if the data is uploading in a prompt fashion. Average watts 82 for the time period are displayed as well as a projection of Yearly KWH usage 83. Chart display 100 displays usage data in a graphical fashion using bar chart 101 to summarize data.

The system, in this implementation, analyzes power usage by sampling the current waveform and voltage waveform for approximately 250 milliseconds. This yields several hundred samples. In order to determine line voltage, an RMS algorithm is used on the samples, in this implementation. To determine Volt Amperes, an RMS value of the current draw may be determined and then multiplied by the line voltage. To determine the watts power consumption, the individual samples of voltage waveform and current waveform may be multiplied together and the divided by the number of samples. One application of the system may be to monitor power usage for individual renters in a facility.

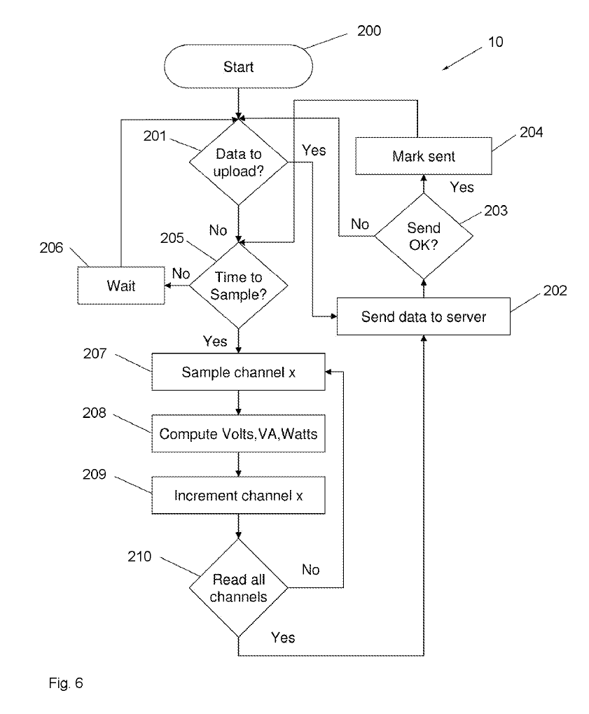

FIG. 6 represents an exemplary flow chart of operations. This exemplary process begins with 200 to start operations. With continuing reference to the exemplary process of FIG. 6, if there is data to upload that was not previously sent, the system will try to send data to the server 202. If this data is sent OK 203, it is marked sent 204. The system samples data once per minute and if it is time to sample 205, the sampling process begins. Sampling occurs on each of 14 or 42 channels for 250 milliseconds typically 207, and the Volts, Volt Amperes and Watts are computed 208. Channel is incremented 209 until all channels are complete in the unit 210. The system then tries to send the new data to the server. If there is no data to upload and it is not time to sample, the system will wait.

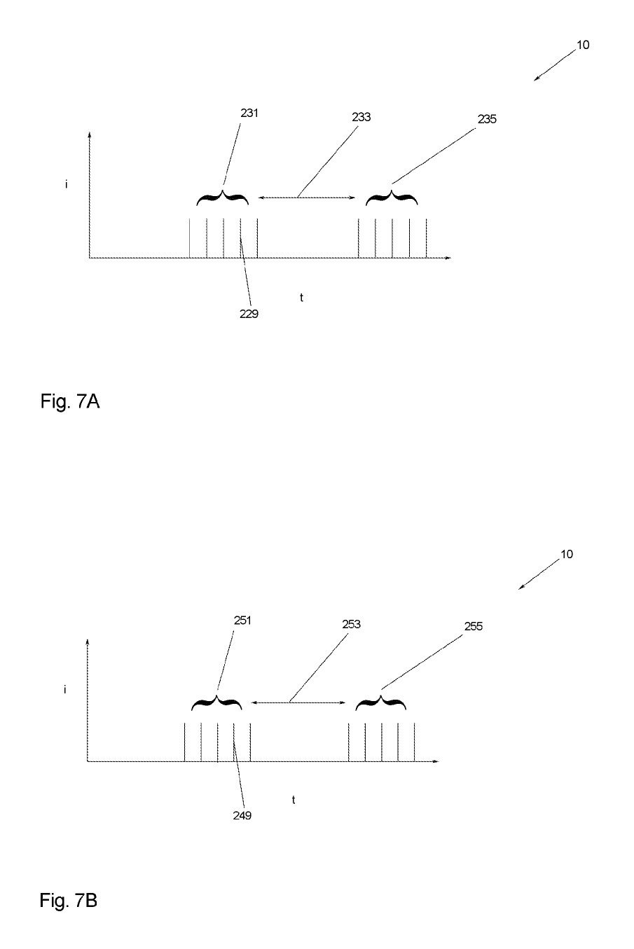

FIG. 7A illustrates an implementation of intermittent sampling of a current transformer signal from the current transformer 34 indicative of the current within circuit 56. With continuing reference to the implementation illustrated in FIG. 7A, the current transformer signal is sampled intermittently by converter 42 such that the current transformer signal is sampled during sampling period 231 and is not sampled during rest period 233. Sampling period 231 may range from about 100 milliseconds to about 1.5 seconds, in various implementations, and rest period may range from about 10 seconds to about 59 seconds. The converter 42 may capture discrete samples 229 of the current transformer signal during the sampling period 231. The number of discrete samples 229 of the current transformer signal may range from about 200 to over 2500, in various implementations, and the sampling rate may range from about 1000 samples per second to over 10000 samples per second.

FIG. 7B illustrates graphically an implementation of intermittent sampling of a reference voltage signal from the reference voltage transformer. With continuing reference to the implementation illustrated in FIG. 7B, the reference voltage signal is sampled intermittently by converter 42 such that the reference voltage signal is sampled during sampling period 251 and is not sampled during rest period 253. Sampling period 251 may range from about 100 milliseconds to about 1.5 seconds, in various implementations, and rest period may range from about 10 seconds to about 59 seconds. The converter 42 may capture discrete samples 249 of the reference voltage signal during the sampling period 251. The number of discrete samples 249 may range from about 200 to over 2500, in various implementations, and the sampling rate may range from about 1000 samples per second to over 10000 samples per second.

In various implementations, the converter 42 may sample the current transformer(s) and the voltage reference signal(s) concurrently, serially, or in various other orders. For example, sampling period 231 may be generally concurrent with sampling period 251 in some implementations or sampling period 231 may be offset from sampling period 251 in other implementations.

The foregoing discussion along with the Figures discloses and describes various exemplary implementations. These implementations are not meant to limit the scope of coverage, but, instead, to assist in understanding the context of the language used in this specification and in the claims. Upon study of this disclosure and the exemplary implementations herein, one of ordinary skill in the art may readily recognize that various changes, modifications and variations can be made thereto without departing from the spirit and scope of the inventions as defined in the following claims.

What is claimed is:

1. A branch circuit power monitoring apparatus comprising:
a current transformer adapted to communicate with a circuit that receives power from an electrical panel to detect the current within the circuit; and
a converter in operable connection with the current transformer to sample intermittently a current transformer signal from the current transformer indicative of the current, the converter adapted to generate a digital data signal indicative of the current.

2. The apparatus, as in claim 1, further comprising:
a reference voltage transformer in operable connection with the converter, the converter intermittently samples reference voltage signal from the reference voltage transformer indicative of a reference voltage of the circuit.

3. The apparatus, as in claim 2, further comprising:
a voltage divider configured to connect the current transformer and the reference voltage transformer to a voltage divider voltage approximately midway between a positive voltage and ground.

4. The apparatus, as in claim 2, wherein the converter samples reference voltage signals for a period of about 250 milliseconds during a 1 second interval.

5. The apparatus, as in claim 2, further comprising:
a microcontroller adapted to receive from the converter a digital signal indicative of the reference voltage and a second digital signal indicative of the current.

6. The apparatus, as in claim 2, wherein the microcontroller is adapted to convert the digital signal and the second digital signal into a value indicative of the power transmitted by the circuit.

7. The apparatus, as in claim 6, further comprising:
a remote server in communication with the microcontroller.

8. The apparatus, as in claim 2, further comprising:
a second reference voltage transformer in operable connection with the converter, the converter intermittently samples second reference voltage signals from the second reference voltage transformer indicative of a second reference voltage;
a third reference voltage transformer in operable connection with the converter, the converter intermittently samples third reference voltage signals from the third reference voltage transformer indicative of a third reference voltage; and
wherein the electrical control panel is connectable to a three-phase power supply, the reference voltage, the second reference voltage, and the third reference voltage indicative of the voltages of each phase of the three phase power supply respectively.

9. The apparatus, as in claim 1, wherein the current transformer is formed as a split-core current transformer.

10. The apparatus, as in claim 1, wherein the current transformer signal is sampled for a period of about 250 milliseconds during a 1 second interval.

11. The apparatus, as in claim 1, further comprising:
a plurality of said current transformers.

12. The apparatus, as in claim 11, wherein the plurality of current transformers is forty-two in number.

13. The apparatus, as in claim 11, wherein the plurality of current transformers is fourteen in number.

14. The apparatus, as in claim 11, wherein each current transformer of the plurality of current transformers is sampled consecutively.

15. The apparatus, as in claim 11, wherein two or more current transformers of the plurality of current transformers are sampled concurrently.

16. A branch circuit power monitoring apparatus comprising:
a circuit receiving power from a buss bar of an electrical panel;
a current transformer in communication with the circuit to detect the current within the circuit;
a reference voltage transformer adapted to detect a reference voltage within the electrical panel;
a converter in operable connection with the current transformer to sample intermittently current transformer signals from the current transformer indicative of the current, the converter adapted to generate a digital data signal indicative of the current, the converter in operable connection with the reference voltage transformer, to sample intermittently reference voltage signals from the reference voltage transformer indicative of the reference voltage; and
a microcontroller adapted to receive from the converter a digital signal indicative of the reference voltage and a second digital signal indicative of the current, the microcontroller in communication with a remote computer.

17. The apparatus, as in claim 16, wherein the converter samples reference voltage signals for a period ranging from about 100 milliseconds to about 1.5 seconds.

18. A branch circuit power monitoring apparatus comprising:
an electrical panel;
a current transformer adapted to communicate with a circuit of the electrical panel to detect the current within the circuit; and
a converter in operable connection with the current transformer to sample intermittently current transformer signals from the current transformer indicative of the current, the converter adapted to generate a digital data signal indicative of the current.
